(19) United States
(12) Patent Application Publication
(10) Pub. No.: US 2020/0118802 A1
(43) Pub. Date: Apr. 16, 2020

(54) MASKING STRUCTURE FOR A WAFER SUPPORTING PLATE

(71) Applicants: LIN-SHENG LU, Taipei City (TW); Cheng-Chih Hsieh, Taipei City (TW); Hsuan-Chung Chen, Taipei City (TW); Hsin Chih Chiu, Taipei City (TW); Yao-Syuan Cheng, Taipei City (TW); Chun-Fu Wang, Taipei City (TW)

(72) Inventors: LIN-SHENG LU, Taipei City (TW); Cheng-Chih Hsieh, Taipei City (TW); Hsuan-Chung Chen, Taipei City (TW); Hsin Chih Chiu, Taipei City (TW); Yao-Syuan Cheng, Taipei City (TW); Chun-Fu Wang, Taipei City (TW)

(21) Appl. No.: 16/157,093

(22) Filed: Oct. 11, 2018

(51) Int. Cl. H01J 37/34; H01L 21/687; H01J 37/32

(52) U.S. Cl. CPC H01J 37/3441; H01J 37/32715; H01L 21/68771

(57) ABSTRACT

A masking structure for a wafer supporting plate comprises a cavity; a carrying tray having a plurality of recesses in a top surface thereof for receiving a plurality of wafers; the carrying tray can be transferred into and out of the cavity by using a robot; a supporting plate installed within the cavity and below the carrying tray; the supporting plate could move upwards, and downwards; a mask installed within the cavity and above the carrying tray; the mask formed with a plurality of through holes which are positioned and shaped to be corresponding to those of the wafers on the carrying tray; therefore, when the supporting plate lifts the carrying tray to be near the mask, the wafers are exposed out of the through holes.

### FIELD OF THE INVENTION

The present invention relates to wafer manufacturing process, in particular to a masking structure for a wafer supporting plate.

### BACKGROUND OF THE INVENTION

Referring to FIGS. 1 and 2, in plating of films in general semiconductor packaging processes, LED packaging processes, and panel manufacturing processes, for increasing the production rate, generally, the wafers 10 are placed in a carrying tray 11 which is then transferred to a supporting plate 13 of a cavity 12 by using a robot. Then a sputtering device 14 at an upper side of the cavity 12 will sputter atoms from a target so that the atoms are deposited on the wafers 10.

However, in the plating process, the sputtering of atom will pollute the supporting plate 11 locating the wafers 10 (referring to a dashed area in FIG. 2). With the times of plating, the deposited films on the supporting plate will become thicker and thicker so as to induce peeling pollution and particles pollution. Although the deposited film can be removed by chemically washing so that the supporting plate 12 can be used repeatedly, the supporting plate will become thinner with the times of washing and thus become weaker. In the proceeding process, the supporting plate 12 is easy to be destroyed due to mechanically pulling force and change of temperature, even the products are affected and thus are not used. Thus the prior art technology has the defects of shorting the lifetime of the supporting plate, increasing the cost in washing and higher destroying rate of the products.

### SUMMARY OF THE INVENTION

Accordingly, the object of the present invention is to provide a masking structure for a wafer supporting plate, wherein by using the structure of the present invention, due to the masking effect of the mask 60, in sputtering operation, the film from sputtering will not deposit on the carrying tray 30, while it only deposits on the wafers 32 through the through holes 62 of the mask 60. Therefore, the lifetime of the carrying tray 30 is prolonged greatly and the fees for washing the carrying tray 30 is reduced. Furthermore the risk of destroy of the products is also decreased.

To achieve above object, the present invention provides a masking structure for a wafer supporting plate comprises a cavity; a carrying tray having a plurality of recesses in a top surface thereof for receiving a plurality of wafers; the carrying tray can be transferred into and out of the cavity by using a robot; a supporting plate installed within the cavity and below the carrying tray; the supporting plate could move upwards, and downwards; a mask installed within the cavity and above the carrying tray; the mask formed with a plurality of through holes which are positioned and shaped to be corresponding to those of the wafers on the carrying tray; therefore, when the supporting plate lifts the carrying tray to be near the mask, the wafers are exposed out of the through holes.

### BRIEF DESCRIPTION OF THE DRAWINGS

FIG. 1 is FIG. 1 is a schematic view about the prior art plating of wafer.

FIG. 2 is an enlarged schematic view about the supporting plate in the prior art.

FIG. 3 is an exploded schematic view about the cavity according to the present invention.

FIG. 4 is an assembled enlarged view about the cavity of the present invention.

FIG. 5 is a schematic view showing the operation of the sputtering device is transferred into the cavity in accordance to the present invention.

FIG. 6 is a schematic view about the transfer of the supporting plate.

FIG. 7 is an operation schematic view about the process of the plating in accordance to the present invention.

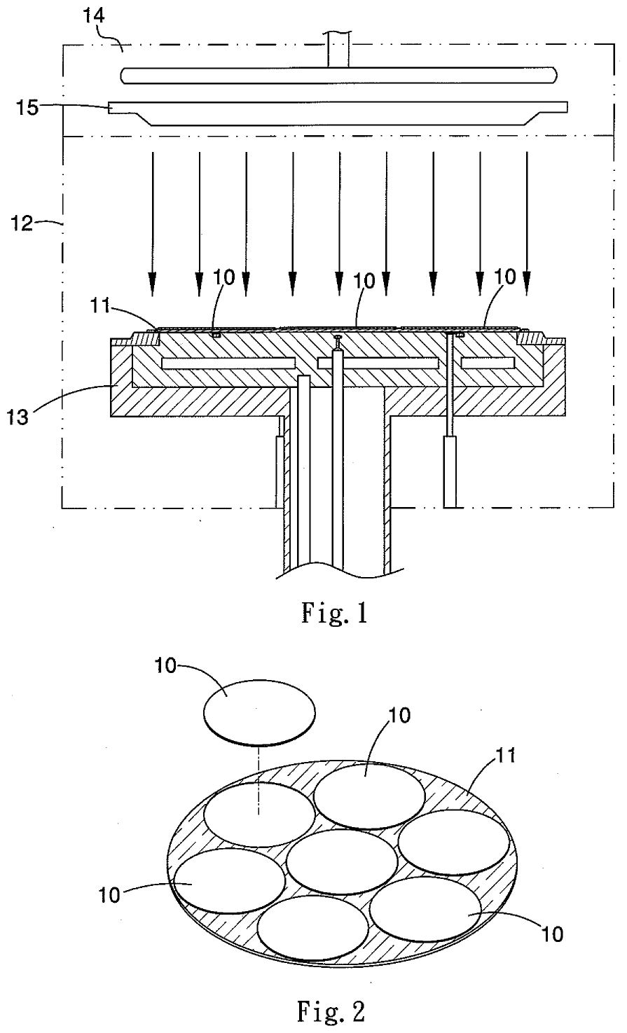

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

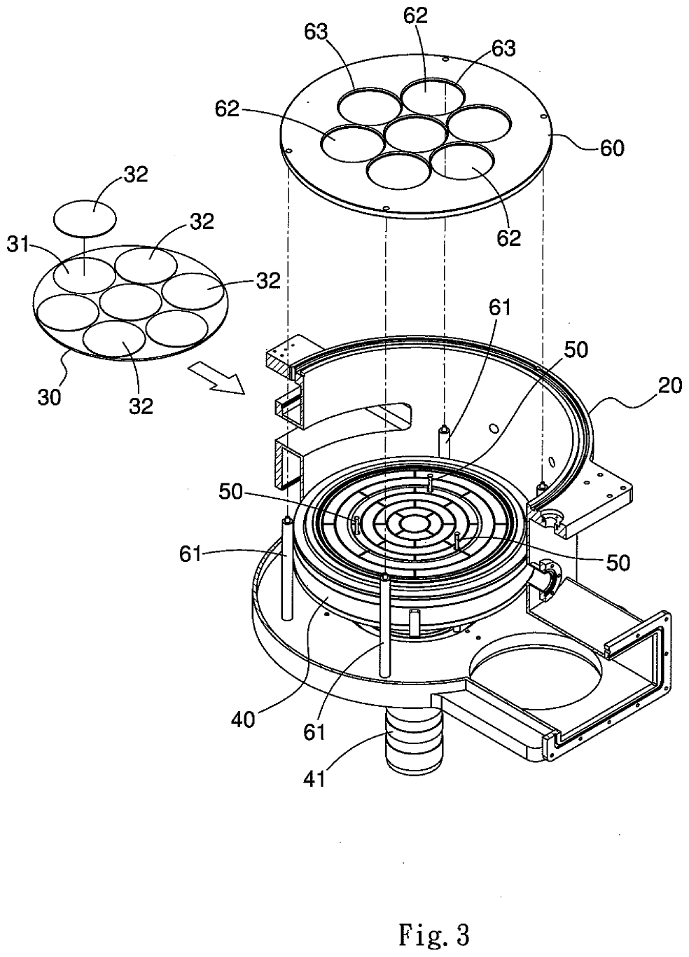

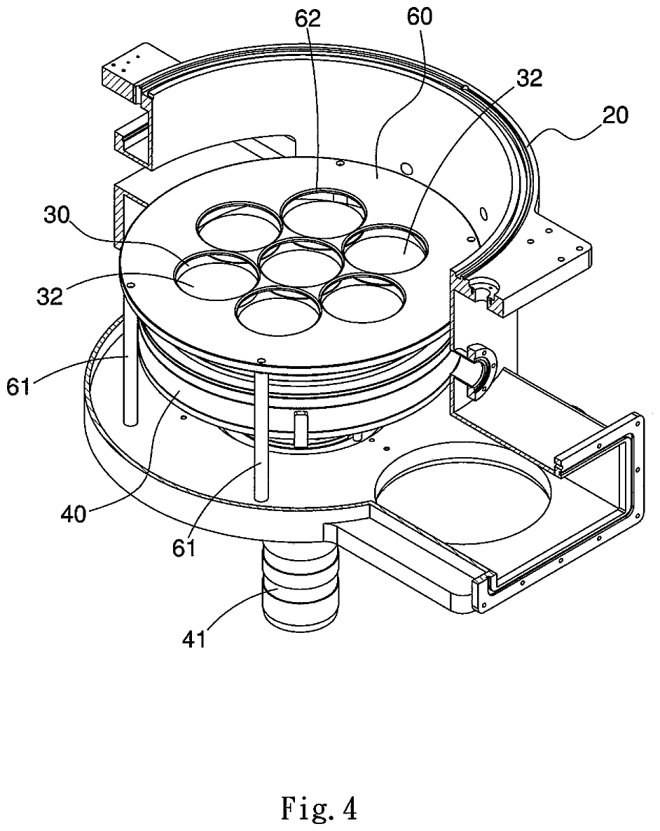

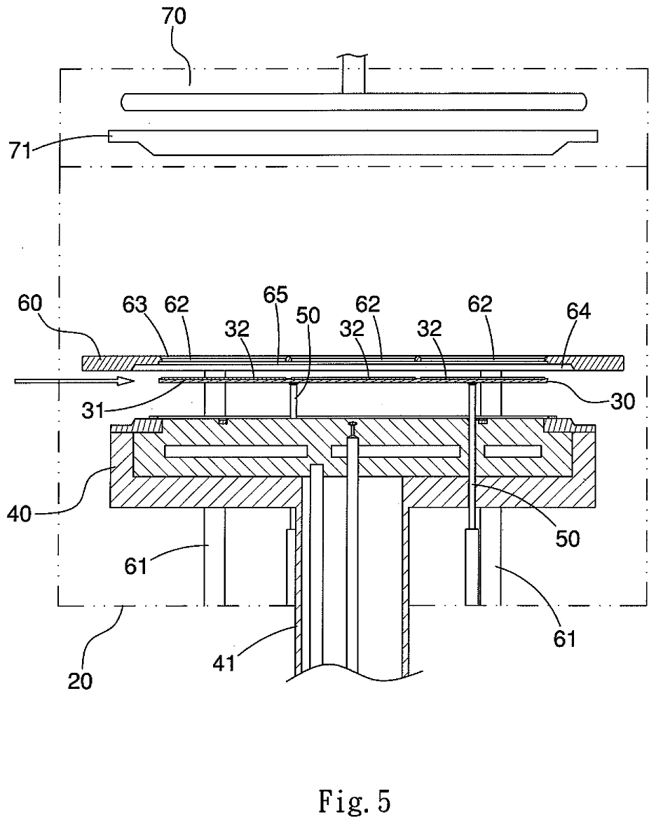

With reference to FIGS. 3 to 7, the structure of the present invention includes the following elements.

A cavity 20 is included.

A carrying tray 30 has a plurality of recesses 31 in a top surface thereof for receiving a plurality of wafers 32. The carrying tray 30 can be transferred into and out of the cavity 20 by using a robot (not shown).

A supporting plate 40 is installed within the cavity 20 and below the carrying tray. The supporting plate 40 could move upwards, and downwards. A bottom side of the supporting plate 40 is installed with a driving rod 41 which extends downwards and penetrating through a lower side of the cavity 20. The driving rod 41 is driven by a driving device (not shown) to move downwards and upwards.

A plurality of top rods 50 are included. A lower part of each top rod 50 is installed at a lower side of the cavity 20 and an upper side of each top rod 50 penetrates through the supporting plate 40. The top rod 50 is liftable for supporting the carrying tray 30 and is descendable to be hidden within the supporting plate 50 so that the carrying tray 30 is placed on a top surface of the supporting plate 40.

A mask 60 is installed within the cavity 20 and above the carrying tray. The mask 60 has a plurality of supporting posts 61 extending from a bottom side of the mask 60 and fixed to the lower surface of the cavity 20 so that the mask 60 is at an upper side of the supporting plate 40. The mask 60 is formed with a plurality of through holes 62 which are positioned and shaped to be corresponding to those of the wafers 32 on the carrying tray 30. Therefore, when the supporting plate 40 lifts the carrying tray 30 to be near the mask 60, the wafers 32 are exposed out of the through holes 62. Each through hole 62 is formed as a trumpet hole 63. A bottom side of the mask 60 is formed with a bottom groove 64 and a bottom side of the bottom groove 64 is formed with a stepped groove 65.

A surface of the mask 60 and a surface of the carrying tray 30 are formed with a plurality of concave portions and convex portions so that the mask 60 can be engaged with the carrying tray 30 and therefore the wafers 32 on the carrying tray 30 may be aligned to the through holes 62 of the mask 60. The convex portions and concave portions may have tapered shapes or semi-spherical shapes.

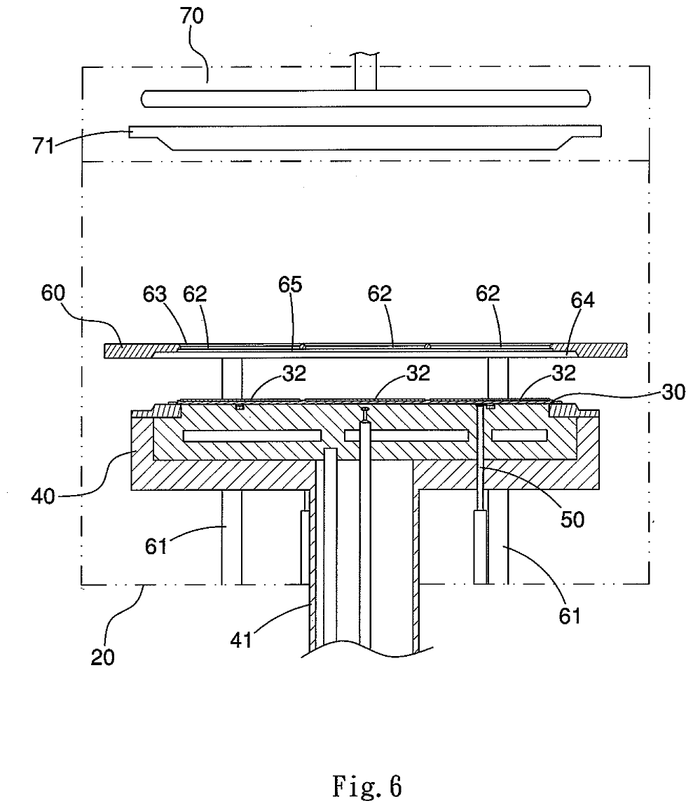

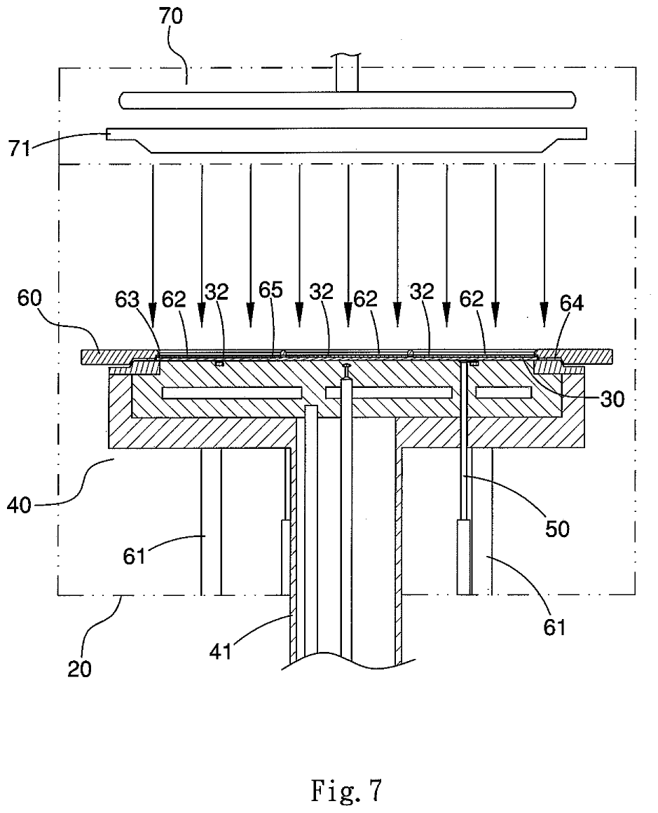

By using the present invention, when a process of plating firm is performed, the plurality of wafers 32 are located in the recesses 31 of the carrying tray 30. Then a robot (not shown) serves to transfer the carrying tray 30 to the cavity 20 so that the upper ends of the top rods 50 may resist against the bottom surface of the carrying tray 30. Then the robot retracts back to be out of the cavity 20 (referring to FIG. 5). Then, the plurality of top rods 50 descends to cause that the carrying tray 30 are placed on a top surface of the supporting plate 40 (referring to FIG. 6). Then, the supporting plate 40 is lifted upwards to a lower side of the mask 60 so that the wafers 32 exposes out from the through holes 62 of the mask 60. Then a sputtering device 70 sputters atoms of a target 71 only to the wafers 32 due to the masking effect of the mask (referring to FIG. 7).

By using the structure of the present invention, due to the masking effect of the mask 60, in sputtering operation, the film from sputtering will not deposit on the carrying tray 30, while it only deposits on the wafers 32 through the through holes 62 of the mask 60. Therefore, the lifetime of the carrying tray 30 is prolonged greatly and the fees for washing the carrying tray 30 is reduced. Furthermore the risk of destroy of the products is also decreased.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A masking structure for a wafer supporting plate; comprising:
a cavity;
a carrying tray having a plurality of recesses in a top surface thereof for receiving a plurality of wafers; the carrying tray can be transferred into and out of the cavity by using a robot;
a supporting plate installed within the cavity and below the carrying tray; the supporting plate could move upwards, and downwards;
a mask installed within the cavity and above the carrying tray; the mask formed with a plurality of through holes which are positioned and shaped to be corresponding to those of the wafers on the carrying tray; therefore, when the supporting plate lifts the carrying tray to be near the mask, the wafers are exposed out of the through holes.

2. The masking structure for a wafer supporting plate as claimed in claim 1, further comprising a plurality of top rods; a lower part of each top rod being installed at a lower side of the cavity and an upper side of each top rod penetrating through the supporting plate; the top rod being liftable for supporting the carrying tray and being descendable to be hidden within the supporting plate so that the carrying tray is placed on a top surface of the supporting plate.

3. The masking structure for a wafer supporting plate as claimed in claim 2, wherein a bottom side of the supporting plate is installed with a driving rod which extends downwards and penetrating through a lower side of the cavity; the driving rod is driven by a driving device to move downwards and upwards.

4. The masking structure for a wafer supporting plate as claimed in claim 2, wherein the mask has a plurality of supporting posts extending from a bottom side of the mask and fixed to the lower surface of the cavity so that the mask is at an upper side of the supporting plate.

5. The masking structure for a wafer supporting plate as claimed in claim 2, wherein each through hole is formed as a trumpet hole.

6. The masking structure for a wafer supporting plate as claimed in claim 2, wherein a bottom side of the mask is formed with a bottom groove and a bottom side of the bottom groove is formed with a stepped groove.

7. The masking structure for a wafer supporting plate as claimed in claim 2, wherein a surface of the mask and a surface of the carrying tray are formed with a plurality of concave portions and convex portions so that the mask can be engaged with the carrying tray and therefore the wafers on the carrying tray are aligned to the through holes of the mask.

8. The masking structure for a wafer supporting plate as claimed in claim 7, wherein the convex portions and concave portions have tapered shapes.

9. The masking structure for a wafer supporting plate as claimed in claim 7, wherein the convex portions and concave portions have semi-spherical shapes.
